(19) United States
(12) Patent Application Publication
(10) Pub. No.: US 2003/0227949 A1
(43) Pub. Date: Dec. 11, 2003

(54) Integrated, temperature insensitive wavelength locker for use in laser packages

(76) Inventor: Mark Meyers, Allentown, PA (US)

Correspondence Address: RATNERPRESTIA, P O BOX 980, VALLEY FORGE, PA, 19482-0980, US

(21) Appl. No.: 10/337,443

(22) Filed: Jan. 7, 2003

Related U.S. Application Data
(60) Provisional application No. 60/386,171, filed on Jun. 5, 2002.

(51) Int. Cl. H01S 3/098; H01S 3/13; H01S 3/04; H01S 5/00

(52) U.S. Cl. 372/32; 372/36; 372/50

(57) ABSTRACT

A wavelength selective detector, method of manufacture, and method of operation are disclosed. The wavelength selective detector includes an etalon, first and second collimating optical elements, and first and second optical detectors. The etalon has first and second surfaces, which are substantially parallel. The first collimating optical element has a first focal length to substantially collimate, within the etalon, a first portion of light from a light source. The second collimating optical element has a second focal length, shorter than the first focal length, to substantially collimate, within the etalon, a second portion of light from the light source. The first and second optically collimating optical elements are coupled to first and second optics portions of the first surface of the etalon, respectively. The first and second optical detectors are configured to receive the first and second portions of light, respectively, after they pass through the etalon.

### CROSS-REFERENCE TO RELATED APPLICATIONS

This application claims the benefit of U.S. Provisional Application No. 60/386,171, filed Jun. 5, 2002, the contents of which are incorporated herein by reference.

### FIELD OF THE INVENTION

This invention is in the field of semiconductor laser devices, and specifically relates to the monitoring of optical signals for locking of the wavelength of the optical signal.

### BACKGROUND OF THE INVENTION

Optical monitors are used with many optical devices. They may be used, for example, to determine the wavelength and/or optical power of light produced by a semiconductor laser in order to tune the laser. Optical monitors may also be used to determine the losses in an optical system, such as at an electro-absorptive modulator or semiconductor optical amplifier, by measuring both the input energy and output energy of the system either over a broad band of wavelengths or in a specific narrow band. In the materials that follow, it is assumed that the light to be measured is propagating through a waveguide or is generated in an optical gain medium. In the material that follows, the term “waveguide” includes both traditional waveguides and gain media. Furthermore, the term light is used to indicate any radiation that may be transmitted via an optical waveguide.

An important use for optical monitoring systems is in tuning communications lasers. Communications lasers operating in a dense wavelength division multiplexing (DWDM) system are desirably especially finely tuned to be able to provide the closely spaced channels defined for this standard. DWDM systems require the ability to control the frequency of any transmission source to within +/−2 GHz in order to allow the use of multiple transmission frequencies in the C and L band. These frequencies are determined by the internationally accepted ITU frequency standards. Exemplary channels for a DWDM system are defined as νₙ=ν₀±ndν, where ν₀ is the central optical frequency, (e.g. 193.1 THz) and dν is the channel spacing (e.g. 100 GHz or of 50 GHz).

Typical semiconductor lasers may be tuned in a range of 30-40 nm while maintaining acceptable power levels. Tunable semiconductor lasers may be distributed feedback (DFB) lasers, distributed Bragg reflector (DBR) lasers, or more conventional lasers having a resonant cavity that includes at least one Fabry-Perot cavity as a reflector. In each of these lasers, the resonant wavelength may be tuned by electrically or thermally adjusting the “optical length” between the reflectors. The optical length may be adjusted by changing the actual length (i.e. mechanically adjusting the cavity length through thermally induced variation in thickness or piezoelectric effects) and/or by adjusting the index of refraction of the material between the reflectors. Although not explicitly described herein, pressure, as applied by one or more piezoelectric elements, may also be used to adjust the index of refraction.

Since laser diode sources exhibit changes in output wavelengths as a function of temperature, drive current and aging it is desirable that they be attached to a wavelength locking unit.

A laser tuning system may utilize the output light provided by the laser that is coupled to a waveguide. A portion of the light traveling through the waveguide is tapped, for example, by splicing an optical fiber through the cladding of the waveguide. This tapped light may be applied to one or more optical filters that separate light having a particular wavelength and then to an optical sensor, such as a photodiode. The light tapped from the waveguide may also be directly detected by an optical sensor to determine the power level of the laser. Splicing optical fibers to the output fiber to tap the light may cause undesirable power loss or scattering of light that may result in increased noise or feedback into the laser. Alternatively, leakage light from the back facet of a semiconductor laser may be used to monitor the output wavelength of the laser.

The signals provided by the optical sensors may be applied to control circuitry that adjusts the temperature of the laser or its reflectors or adjusts an electrical potential applied to the reflectors (for DBR lasers) to control the refractive index. This circuitry utilizes the relationship of resonant wavelength to temperature to change the resonant wavelength of the laser and desirably center it within a predetermined communications channel.

Thus, considerable circuitry, separate from the semiconductor laser, is typically used to tune the laser.

Alternatively, wavelength locking of a laser may be implemented by either splicing in an external fiber Bragg grating or another form of an external locking module, or by incorporating an etalon or dielectric filter based locker into the laser package.

The use of an externally spliced-in wavelength control unit is expensive and requires significant space in the product housing. This is due to the need for precise placement of very small objects within the package. This operation invloves cutting the fiber and slicing (typically by melting) the output of the device to the input of the external monitor. The external monitor also may be housed in an additional package external to the laser package, further adding to the total space requirements. An external monitor may also be added by splicing the output of the external monitor in line. Typically, there is a requirement for a minimum distance from the facet of the laser to a collimating optic and an additional minimum space between the collimating optic, the etalon and the monitoring photodiodes. Each component may require active placement in the package to achieve the required precision.

The use of internal filter based lockers provide a wavelength dependent transmission signal, but the sensitivity to wavelength changes is significantly lower than that of etalon based lockers. They are also only useable over a small wavelength range of 1 to 2 nm. Typically, filter based lockers are used for locking on only 1 to 3 wavelengths in the ITU grid.

Etalon based wavelength lockers have a periodic transmission versus wavelength characteristic, which allows them to be used over a very wide tuning range (the entire C and L band). However, because the transmission of the etalon versus wavelength depends on the optical thickness of the etalon, the system may suffer from sensitivity to etalon temperature due to refractive index and thickness variations of the etalon with temperature. Also, etalon based lockers require active alignment in the laser package to within 0.1° due to the very high slope of the transmission versus wavelength characteristic. The wavelength versus transmission characteristic for an etalon is periodic. There are regions of very low slope at the peaks and valleys of the transmission characteristic. If the laser frequency happens to fall on either a peak or a valley, where the low slope regions occur, the etalon based locker may not be able to accurately lock the laser. For a widely tunable laser, even if the etalon is accurately aligned in the laser package, the laser wavelength can eventually fall on a low slope region for a single etalon type of locker.

Prior art solutions for the use of etalons over wide tuning ranges have involved the use of stepped etalons. Stepped etalons are formed so that the thickness of one section of the etalon is larger than for the other section. This leads to a relative change in the phase of the transmission versus wavelength change for the two section etalons. By proper control of the etch step thickness the position of the transmission maximum and minimum for the two etalon characteristic curves can be adjusted such that there is a high slope region in at least one of the curves over a large range of wavelengths.

This may be described more easily with reference to FIG. 1. FIG. 1 is a graph of amplitude versus wavelength that illustrates the response of two etalons having different optical thicknesses. In FIG. 1, graph 100 represents the response of an etalon having a first optical thickness and graph 102 represents the response of an etalon having a slightly different optical thickness. As shown by the lines 104 and 106, which may represent wavelengths of interest, the peak in the response of one etalon corresponds to the mid-point in the slope of the response of the other etalon over a significant frequency range.

The difference in thickness of the etalon portions leads to a shift in transmission peaks of the etalons as the wavelength varies from the intended wavelength region, as illustrated in FIG. 1 by lines 108 and 110, which represent wavelengths with low slopes for both graph 100 and graph 102. This limits the desirable bandwidth of such stepped etalon wavelength locker, but the desirable bandwidth of this locker is typically several times larger than the desirable bandwidth of a single etalon wavelength locker. U.S. Pat. No. 6,323,987 entitled, CONTROLLED MULTI-WAVELENGTH ETALON, describes a method of tuning a laser using the slope of a response curve. This method may be desirable because relatively small changes in the frequency of the laser light can be sensed and corrected.

One limitation encountered in such a system is that the solid etalon in which the step is etched into may be subject to thermally induced variations in the substrate refractive index and reflector to reflector thickness. It is also sensitive to the quality of collimation of the incident beam and may not operate properly if the etalon is not located symmetrically.

### SUMMARY OF THE INVENTION

One embodiment of the present invention is an exemplary wavelength selective detector. The exemplary wavelength selective detector includes an etalon, a first collimating optical element, a second collimating optical element, a first optical detector, and a second optical detector. The etalon has first and second surfaces, which are substantially parallel to one another. The first collimating optical element, which has a first focal length to substantially collimate, within the etalon, a first portion of light from a light source, is optically coupled to a first optics portion of the first surface of the etalon. The second collimating optical element, which has a second focal length, shorter than the first focal length, to substantially collimate, within the etalon, a second portion of light from the light source, is optically coupled to a second optics portion of the first surface of the etalon. The first and second optical detectors are configured to receive the first and second portions of light from the light source, respectively, after they pass through the etalon.

Another embodiment of the present invention is an alternative exemplary wavelength selective detector. This alternative exemplary wavelength selective detector includes a base having a top surface, a first substrate, and a second substrate, which are substantially transparent to a wavelength of interest and coupled to the top surface of the base. The first substrate has an optics surface and a first reflecting surface, which are substantially perpendicular to the top surface of the base. First and second collimating optical elements are formed on first and second optics portions of the optics surface, respectively. The first collimating optical element has a first focal length to substantially collimate, within the etalon, a first portion of light from a light source and the second collimating optical element has a second focal length, shorter than the first focal length, to substantially collimate, within the etalon, a second portion of light from the light source. The second substrate has a second reflecting surface and a detector surface, which are substantially perpendicular to the top surface of the base. The second reflecting surface is substantially parallel to and facing the first reflecting surface of the first substrate. A first optical detector is optically coupled to a first detector portion of the detector surface and a second optical detector is optically coupled to a second detector portion. The first and second optical detectors are configured to receive the first and second portions of light from the light source, respectively, after they pass through the second substrate.

A further embodiment of the present invention is an exemplary method of manufacturing a wavelength selective detector. A substrate is provided which has a first index of refraction, a front surface, and a back surface substantially parallel to the front surface. The front surface of the substrate has a first portion and a second portion. A first photodetector is coupled to a first region of the back surface of the substrate corresponding to the first portion of the front surface of the substrate and a second photodetector is coupled to a second region of the back surface of the substrate corresponding to the second portion of the front surface of the substrate. A dielectric lens layer is formed over the front surface of the dielectric substrate, which has a second index of refraction that is less than the first index of refraction. The dielectric lens layer is etched to form a first lens section corresponding to the first portion of the front surface of the substrate, and a second lens section corresponding to the second portion of the front surface of the dielectric substrate. These lens sections may be either diffractive or refractive optics sections. The first lens section has a first focal length and the second lens section has a second focal length that is shorter that the first focal length.

Yet another embodiment of the present invention is an exemplary method of manufacturing a wavelength selective detector. A substrate is provided which has a first index of refraction, a front surface, and a back surface substantially parallel to the front surface. The front surface of the substrate has a first portion and a second portion. A first photodetector is coupled to a first region of the back surface of the substrate corresponding to the first portion of the front surface of the substrate and a second photodetector is coupled to a second region of the back surface of the substrate corresponding to the second portion of the front surface of the substrate. A first dot of photoresist having a first radius and a second dot of photoresist having a second radius are formed on the front surface of the substrate. The photoresist has a second index of refraction that is less than the first index of refraction. The first and second dots of photoresist are heated to form a first lens and a second lens. The first lens corresponds to the first portion of the front surface of the dielectric substrate and has a first focal length. The second lens corresponds to the second portion of the front surface of the substrate and has a second focal length that is shorter that the first focal length.

A still further embodiment of the present invention is an exemplary method of detecting a wavelength of output light of a laser using leakage light from the laser. A first portion of the leakage light is coupled into an etalon through a first collimating optic, which has a first focal length. A second portion of the leakage light is coupled into the etalon through a second collimating optic, which has a second focal length that is shorter than the first focal length. The first portion of the leakage light is attenuated, in intensity, in the etalon based on the wavelength of the output light of the laser and first predetermined criteria. The first predetermined criteria include the focal length of the first collimating optic. The second portion of the leakage light is attenuated, in intensity, in the etalon based on the wavelength of the output light of the laser and second predetermined criteria. The second predetermined criteria include the focal length of the second collimating optic. The intensities of the attenuated first and second portions of the leakage light are measured. The wavelength of the output light of the laser is determined based on measurements, which include the measured intensity of the attenuated first portion of the leakage light and the measured intensity of the attenuated second portion of the leakage light, and parameters, which include the first focal length and the second focal length.

Yet another embodiment of the present invention is an exemplary semiconductor laser chip including a semiconductor laser and an optical detector to monitor a detection portion of the optical leakage from the rear facet of the semiconductor laser. The semiconductor laser chip includes a mounting substrate, the semiconductor laser, and an optical detector. The mounting substrate, which includes a dielectric material, has a diffraction grating on a portion of its top surface. The diffraction grating has a grating period selected to substantially diffract incident light of a predetermined range of wavelengths from the laser in a predetermined range of angles relative to the top surface of the mounting substrate. The semiconductor laser is adapted to produce light in this predetermined range of wavelengths and is coupled to the mounting substrate such that a rear facet of the semiconductor laser is adjacent and substantially perpendicular to the diffraction grating portion of the top surface of the mounting substrate. The optical detector is configured such that the detection portion of the optical leakage from the rear facet of the semiconductor laser is incident on the it, but the portion of the optical leakage from the rear facet of the semiconductor laser diffracted by the diffraction grating portion is not incident of the optical detector.

An additional embodiment of the present invention is an exemplary air-spaced etalon including a first substrate, a second substrate, and a spacer configured to hold the first substrate and the second substrate in a predetermined spatial relationship. The first substrate is substantially transparent to a wavelength of interest and has a first reflecting surface. The second substrate is also substantially transparent to the wavelength of interest and has a second reflecting surface. The second reflecting surface of the second substrate is substantially parallel to and facing the first reflecting surface of the first substrate. The spacer has a coefficient of thermal expansion in the range of about 0.3×10−6 per ° C. and about 1.0×10−6 per ° C.

### BRIEF DESCRIPTION OF THE DRAWINGS

The invention is best understood from the following detailed description when read in connection with the accompanying drawing. It is emphasized that, according to common practice, the various features of the drawing are not to scale. On the contrary, the dimensions of the various features are arbitrarily expanded or reduced for clarity. Included in the drawing are the following figures:

FIG. 1 is a graph of wavelength versus amplitude that is useful to describe the operation of the embodiments of the present invention.

FIG. 2 is a flowchart illustrating an exemplary method of locking the output wavelength of a laser.

FIG. 3A is a front plan drawing of the exemplary etalon based wavelength locking device.

FIG. 3B is a top cut-away drawing of the exemplary etalon based wavelength locking device along 3B-3B of FIG. 3A.

FIG. 4 is a flowchart illustrating an exemplary method of manufacture of the exemplary etalon based wavelength locking device of FIGS. 3A and 3B.

FIG. 5 is a top plan drawing of an exemplary etalon based wavelength locking device during manufacture according to the flowchart of FIG. 4.

FIGS. 6 and 7 are top cut-away drawings of an exemplary etalon based wavelength locking device along 3B-3B of FIG. 3A during manufacture according to the flowchart of FIG. 4.

FIG. 8 is a top plan drawing of another exemplary etalon based wavelength locking device.

FIG. 9 is a side plan drawing of an exemplary etalon based wavelength locking device and an exemplary substrate grating to reduce unwanted reflections from rear facet leakage light.

FIGS. 10A and 10D are front plan drawings illustrating alternative exemplary collimating lens designs.

FIGS. 10B and 10C are top cut-away drawings illustrating alternative exemplary collimating lens designs along 3B-3B of FIG. 3A.

FIG. 11 is a top plan drawing of an alternative exemplary etalon based wavelength locking device.

FIG. 12 is a top plan drawing of an additional exemplary etalon based wavelength locking device.

FIG. 13 is a back plan drawing of an exemplary air-spaced etalon substrate with mounted circuitry.

FIG. 14A is a back plan drawing of an exemplary air-spaced etalon substrate with integrated circuitry.

FIG. 14B is a top plan drawing of an exemplary air-spaced etalon substrate with integrated circuitry.

### DETAILED DESCRIPTION

The present invention involves the design and use of etalon based wavelength lockers for laser systems. One advantage of etalon based wavelength lockers is that they may utilize leakage light from the rear facet of a semiconductor laser. Using this leakage light alleviates the need to splice a fiber tap into the output fiber of the laser. Additionally, when using rear facet leakage light, it may be possible to position the etalon based wavelength locker near the rear facet within the laser module reducing the overall space used for the laser and locker. It is noted that, although the following descriptions focus on etalon based lockers which use rear facet leakage light, the disclosed designs and method may be practiced using light from a spliced fiber tap or other means of sampling a laser output signal.

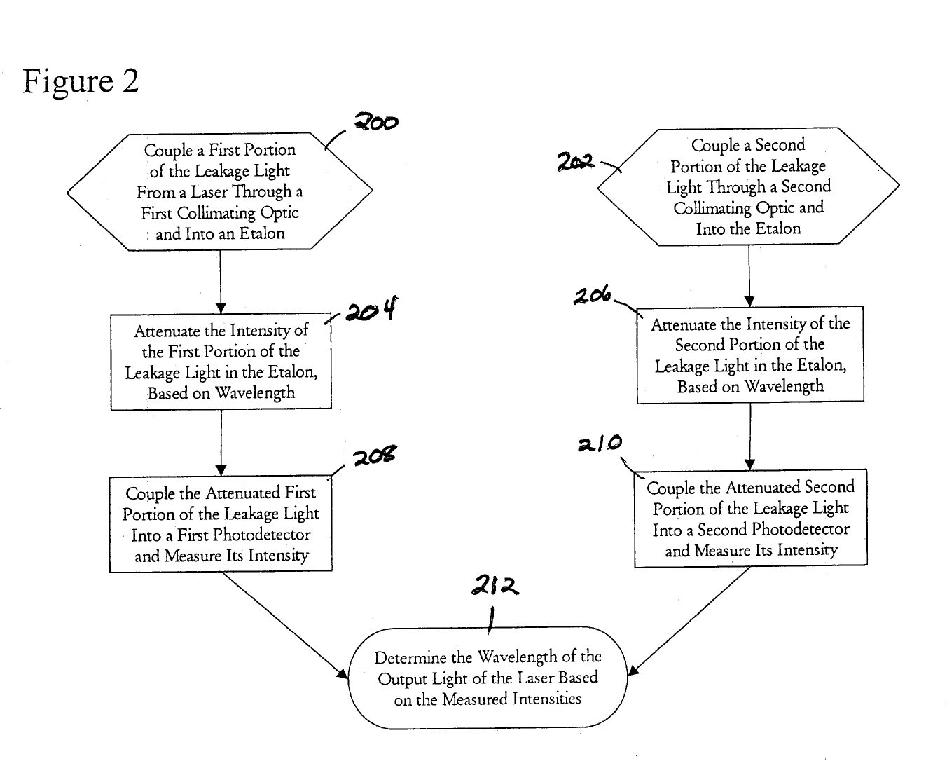

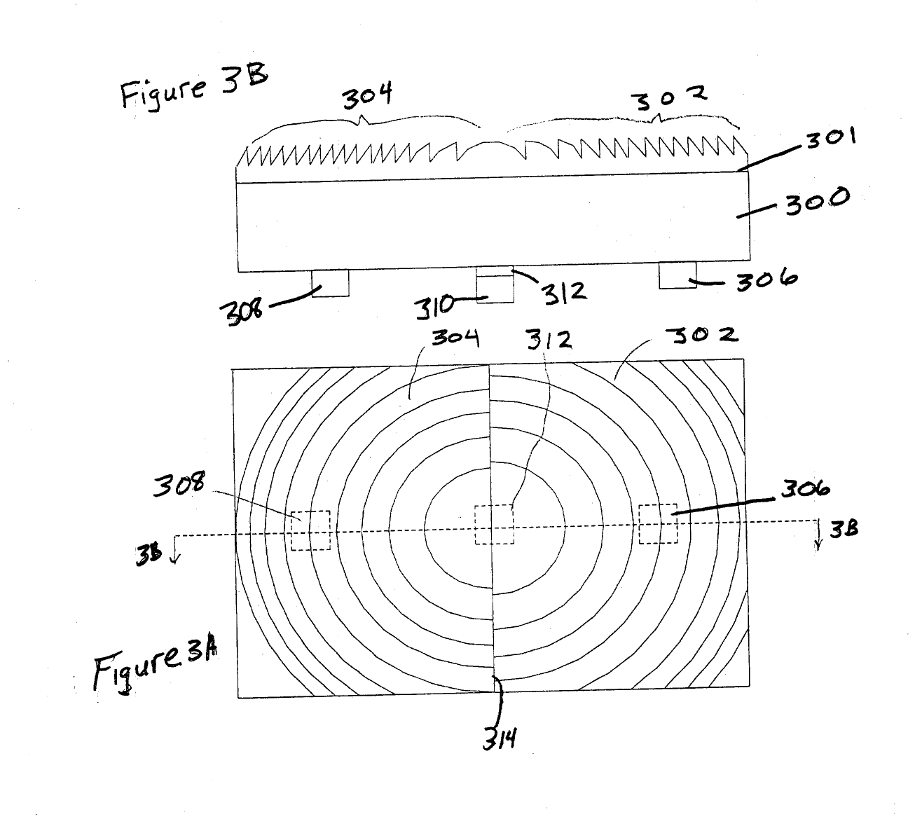

One exemplary embodiment of the present invention, described in the flowchart of FIG. 2, is a method of operating an etalon based wavelength locker. The exemplary method involves the use of a pair of collimating optical elements and a single thickness etalon. FIGS. 3A and 3B illustrate one exemplary embodiment of an etalon based wavelength locker that may be used with the method of FIG. 2. FIG. 3A is a front plan drawing of the exemplary wavelength locker and FIG. 3B is a top cut-away view of this exemplary locker along cut line 3B-3B.

A portion of the leakage light from the rear facet of the laser is coupled into a first collimating optic which substantially collimates the incident leakage light and then couples the leakage light into a portion of the etalon, step 200. Another portion of the leakage light is similarly substantially collimated and coupled into another portion of the etalon by a second collimating optic, step 202. The two collimating optic sections may be diffractive, refractive, or hybrid lenses, and may be separate from the etalon or may be monolithically integrated onto front surface 301 of the etalon 300, as illustrated by first diffractive collimating optic 302 and second diffractive collimating optic 304 in FIG. 3B. Front surface 301 is desirably a flat reflective surface and may be coated to increase its reflectivity. Monolithic integration allows diffractive collimating optics 302 and 304 to be pre-aligned with the etalon 300. The alignment sensitivity may be reduced, while the space required in the package is also minimized.

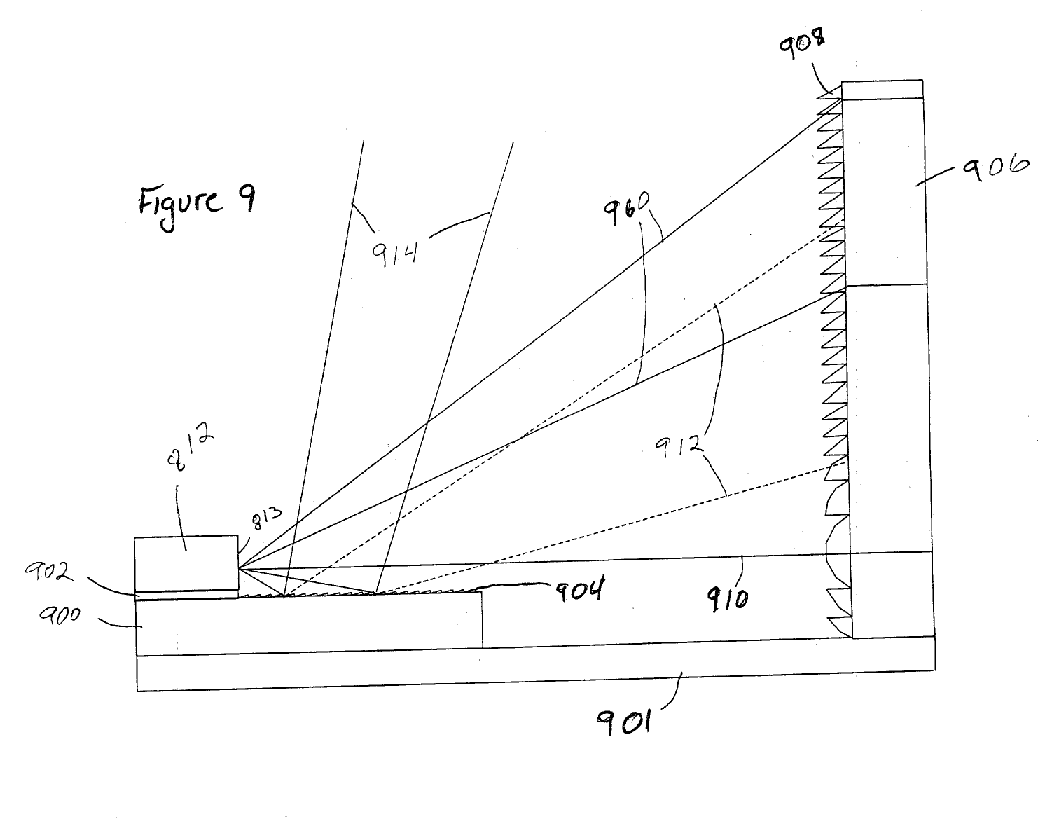

The substantially collimated light from the first collimating optic is partially reflected by both the front surface of the etalon and the back surface of the etalon, creating a standing wave interference pattern between the front and back surfaces of the etalon. This leads to a wavelength dependent attenuation of the transmitted light, step 204. In the case of an air-spaced etalon, as shown in FIG. 8, the surfaces of substrates 802 and 804 that face each other are the substantially parallel, partially reflecting surfaces of the etalon. The resulting interference of light reflecting off the front surface and the back surface leads to the well-known transmission versus wavelength spectrum of a Fabry-Perot etalon. The substantially collimated light from second collimating optic is similarly attenuated by the etalon, step 206.

The first collimating optic and the second collimating optic have different focal lengths. Thus, at most one of the two collimating optics may fully collimate the light passing through it and the two substantially collimated beams enter the etalon with different wavefront orientations relative to the front and back surfaces of the etalon. It is noted that the transmission versus wavelength spectrum of a Fabry-Perot etalon is dependent on the orientation of the wavefront relative to the front and back surfaces of the etalon. (See Equation 2, below) Therefore, the difference in the focal lengths of the two collimating optics leads to a relative phase difference in the transmission versus wavelength spectrum of the etalon for light passing through the two collimating optics.

For a diffractive lens the focal length is proportional to the diffractive ring radius for a given fringe diameter. The paraxial diffractive ring radius, Rₘ, for a diffractive lens with a given focal length F is given by:

Rₘ=\sqrt{2mλF} (Equation 1)

where m is the ring order (integer) and λ is the incident wavelength.

By increasing or decreasing the ring radius, the focal length may be made longer or shorter. A change in focal length of a few percent, or less, may desirably shift the peak transmission of each section by a fixed fraction of the free spectral range.

Control of the shift in focal length of a diffractive optic of this type may be extremely stable due to the use of lithographic processing to form the diffractive rings. Alternatively, refractive micro-lenses may be formed with separate portions having different focal lengths by changing the lens radius of curvature. Lithographic processes may adjust design features of the collimating optics to within 0.25 μm, or less.

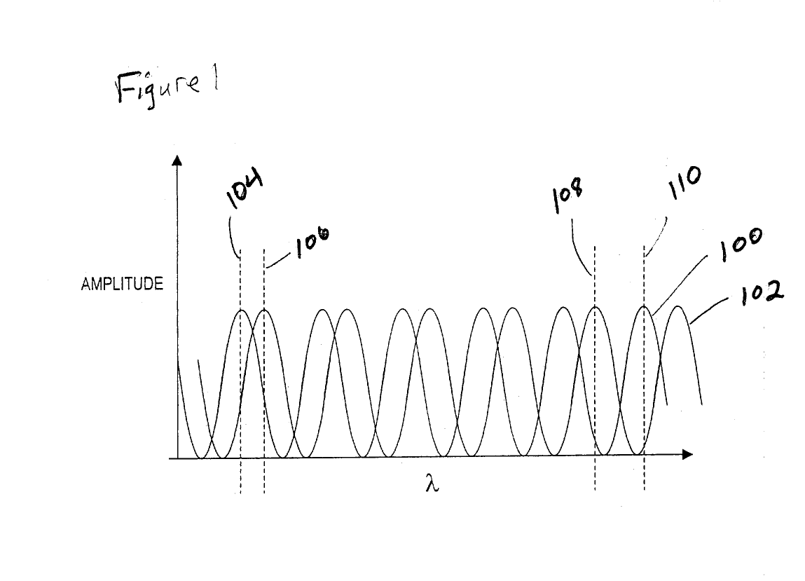

The focal lengths of the collimating optics and the optical thickness of the etalon may be selected to create a transmission versus wavelength graph as shown in FIG. 1, where graph 100 may represent light coupled through the first collimating optic and graph 102 may represent light coupled through the second collimating optic. It is noted that transmission versus wavelength graphs 100 and 102 in FIG. 1 both represent the transmission of an etalon with a relatively low reflectivity, and consequently a relatively low finesse. This is desirable to broaden the peaks and increase the regions of high slope in the graph. The material of the etalon may be selected to provide the desired reflectivity. Additionally, it is desirable for the material of the etalon to have a low absorption in the wavelength band of interest and low thermal expansion. The etalon is desirably mounted to the same base as the laser to be locked. It is undesirable for the transmission versus wavelength spectra of the etalon change significantly with temperature, either due to thermal expansion or change of refractive index of the etalon. One exemplary solution to this problem is the use of an air-gap etalon, described below with reference to FIG. 8.

A portion of the light from the first collimating optic is coupled into a first photodetector after passing through the etalon, step 208. Likewise, a portion of the light from the second collimating optic is coupled into a second photodetector after passing through the etalon, step 210. The intensities of both light portions are measured. The wavelength of the laser output light is then determined from these two light intensities, step 212. An additional measurement of the unattenuated output intensity made by a third photodetector may also be used to scale the transmission values for changes in output intensity.

The first and second photodetectors may be positioned near the back surface of the etalon to receive a portion of the light that passed through the first and second collimating optics, respectively. Alternatively, the first and second photodetectors may be mounted directly on the back surface of the etalon, and electrically connected to additional circuitry via flip chip connections or wire bonding. FIG. 3 illustrates an embodiment in which first photodetector 306 and second photodetector 308 are coupled directly to the back surface of etalon 300. FIG. 3 also shows an optional third photo detector 310. Third photodetector 310 is coupled to the back surface of etalon 300 by anti-reflective (AR) coating 312. AR coating 312 reduces reflections in that small portion of the etalon, substantially eliminating the wavelength dependence of the etalon transmission in that portion. Therefore, the third photodetector 310 may be used to monitor the intensity of the laser independent of wavelength.

The intensities of the first and second photodetectors 306 and 308, and possibly the third photodetector 310, may be used to calculate the wavelength based on Equation 2 for etalon transmission or the wavelength may be determined based on a look-up

$${I}_{T} = \frac{{I}_{0}}{1 + [ \frac{4 R}{{( 1 - R )}^{2}} ] {sin}^{2} [ 2 π \frac{n d cos {φ}^{′}}{λ} ]} \qquad ( Equation 2 )$$

table of transmission versus wavelength values for the two portions of the wavelength locker.

where Iₜ is the transmitted intensity, I₀ is the incident intensity, R is the reflectivity of the surfaces, n is the index of refraction of the etalon, d is the thickness of the etalon, φ′ is the transmission angle within the etalon, and λ is the wavelength of the light. Other factors, such as temperature dependence, may be included as well.

The use of an etalon with monolithically integrated diffractive lens collimating optics and photodetectors, as shown in FIGS. 3A and 3B, may greatly reduce the alignment difficulties associated with the use of an etalon based wavelength locker. This is desirable for the creation of an etalon based wavelength locker having a continuous high slope wavelength monitoring signal on either a first photodetector or a second photodetector without active alignment of the etalon assembly in the laser package. Alternatively, integrated refractive lens collimating optics may be used. It is also contemplated that present invention may be practiced with collimating optics that include three or more sections with different focal lengths to provide separate wavelength dependent signals to a corresponding number of photodetectors.

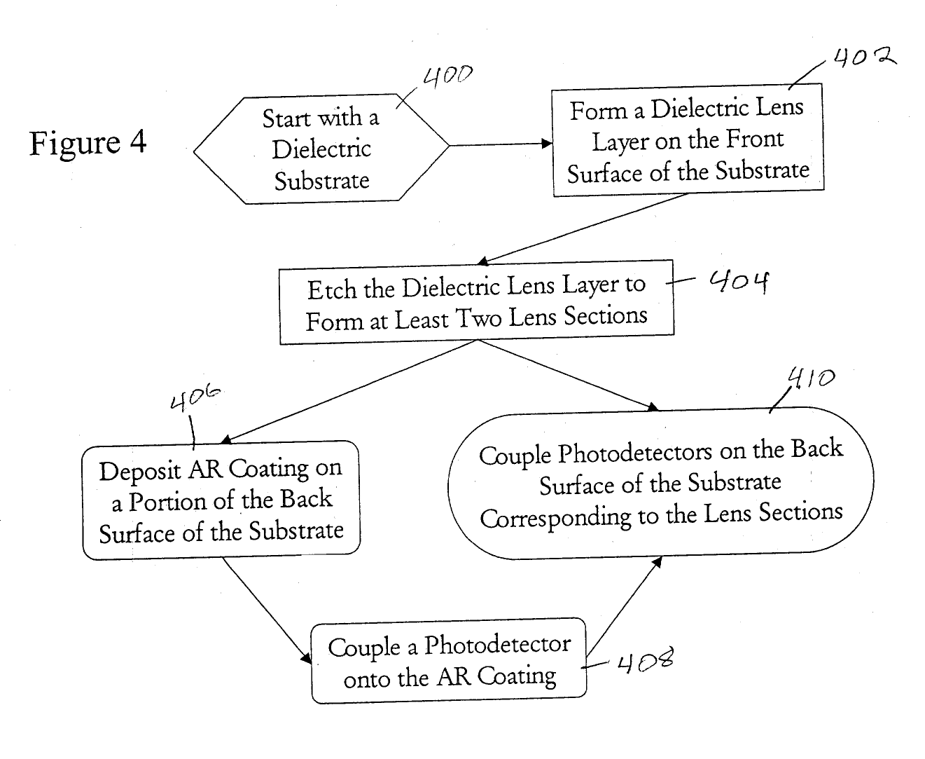

FIG. 4 is a flowchart illustrating an exemplary method for manufacturing a monolithically integrating etalon based wavelength locker of the type shown in FIGS. 3A and 3B. The process begins with a dielectric substrate, which is selected to be the etalon, step 400. For purposes of this description, dielectric materials are assumed to include all solid materials other than metals. The front and back surfaces of the substrate are desirably substantially parallel and may be planarized to provide a smooth reflecting surface for the etalon. The substrate is desirably a material that has low absorptivity in the wavelength band of interest. For C and L band optical communications applications, such materials include a number of optical crystals such as, silicon, germanium, sapphire and NaCl, as well as fused silica, numerous glasses, and optical plastics. A glass ceramic composite, such as Zerodur®, borosilicate glass, or a titanium silicate glass, such as ULE®, may be a particularly desirable substrate material due to the low thermal expansion coefficient of these materials. III/V materials, such as InP, GaAs, InSb, and AlGaAs, may also be desirable substrate materials to allow fabrication of photodetectors within the substrate.

The surfaces of the etalon substrate may be metalized or they may be coated with a dielectric mirror layer to provide adequate reflectivity for the etalon. These coating may be deposited by sputtering, e-beam evaporation, or another standard semiconductor processing technique. It is noted that high finesse etalons have narrower transmission peaks, providing a high slope region over only a small fraction of the free spectral range, the distance between transmission peaks. Therefore, a high finesse etalon may be only desirable to use over a small portion of the free spectral range due to the resulting “gaps” in the wavelength spectra, where their etalon transmission has an extremely low slope and accurately locking the laser may be difficult or impossible. For this reason, wavelength lockers with fixed thickness etalons may be desirably designed with etalons, having low reflectivity surfaces and a finesse on the order of 4 or less.

The relatively low desired etalon finesse may allow a high refractive index material, such as silicon or germanium, to be used as the etalon substrate without a coating layer. For example, silicon has a refractive index of approximately 3.47 for radiation having a wavelength of 1.55 μm, which results in approximately 30% reflectivity for an air/silicon interface. Surfaces such as these may provide sufficient reflectivity to make a low finesse etalon for wavelength monitoring without the use of dielectric or metalized coatings. In the exemplary embodiment illustrated in FIG. 3B front surface 301 of etalon 300 is in direct contact with the collimating optics. The reflectivity of this interface is, therefore, dependent on the indices of refraction of both substrate and the collimating optics materials. For example, a silicon/SiO₂ or silicon/optical epoxy interface may provide a reflectivity of approximately 16%. This reflectivity may be significantly different than the reflectivity of the back surface. Therefore, it may be desirable to form a reflective coating on the front surface of the etalon, even if the back surface is not coated, or to provide different coatings on the front and back surfaces of the etalon to substantially match the reflectivities of these surfaces.

Conductive traces (possibly including metalized bonding pads) to provide electrical connections for photodetectors 306, 308, and 310 may be formed on the back surface of the substrate, as well.

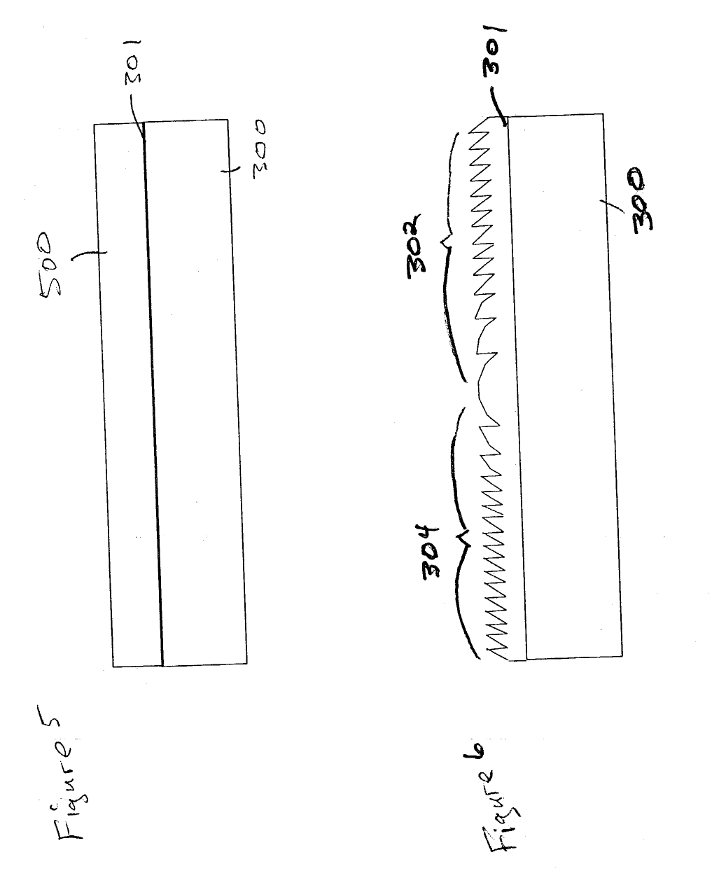

Once the substrate has been selected and prepared, a dielectric lens layer 500 is deposited, step 402, on the front surface of the substrate 300. FIG. 5 illustrates the exemplary method of FIG. 4 following this step of the manufacture. Dielectric lens layer 500 is desirably formed of material having high transmissivity in the wavelength band of interest and a high enough index of refraction, typically greater than 1.2, to provide substantial collimation of the incident light. If substrate 300 is an uncoated dielectric, in order to improve the reflectivity of the front surface of the substrate it may also be desirable for the material of dielectric lens layer 500 to have a low index of refraction relative to the substrate material, desirably one half or less of the refractive index of the substrate. For substrates coated with dielectric mirrors it may be desirable to select a lens material with a relatively low refractive index to improve performance of the dielectric mirror. Numerous glasses and amorphous dielectrics, such as amorphous SiO₂ and SiN, may be used to form the dielectric lens layer, as well as optical epoxies and photoresists. The dielectric lens layer may be deposited by a standard semiconductor fabrication technique, such as sputtering or e-beam evaporation, or, in the case of optical epoxy and photoresist, may be spread on the surface as a liquid and then optically or thermally cured to harden the material into a solid layer. It may be desirable to form the dielectric lens layer as a multilayer structure also.

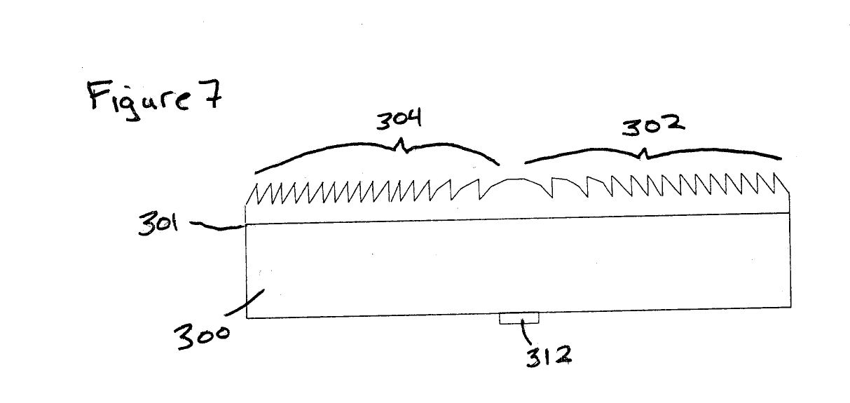

The dielectric lens layer is etched to form at least two lens sections, step 404, which have different focal lengths. FIG. 6 illustrates an exemplary embodiment of an etalon based wavelength locker fabricated according to the exemplary method of FIG. 4 at this step of manufacture. Standard wet or dry etching techniques may be used, depending on the lens material, but anisotropic dry etching may be desirable to control the resulting lens shape. In this exemplary embodiment, two lens sections 302 and 304 are shown as semicircular diffractive lenses and formed side by side as in FIGS. 3A and 3B. It is noted that alternatively lens section 302 and 304 may be formed separately and then coupled to the front surface of the substrate using a substantially transparent adhesive, such as optical epoxy, thermoplastic, or photoresist.

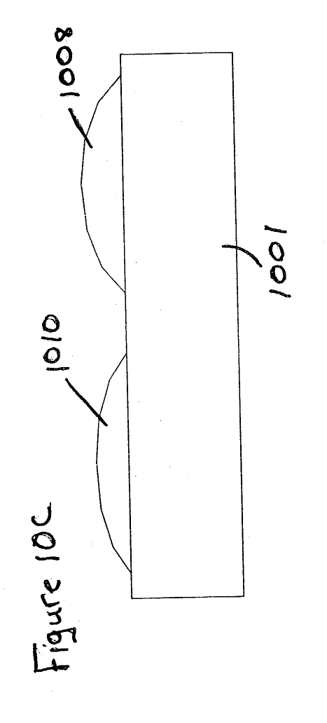

Other arrangements, or numbers, of diffractive lens may be possible, such as two separate circular diffraction lenses 1000 and 1002, set on opposing halves of the front surface of substrate 300 as in FIG. 10A. Alternatively, the lens sections may include refractive lens. Possible arrangements of refractive lens sections include: side by side semicircular lenses 1004 and 1006 as in FIG. 10B and separate circular lenses 1008 and 1010 as in FIG. 10C. Separate circular lens 1008 and 1010 of FIG. 10C may be formed by depositing, or etching, two dots of photoresist and then heating the photoresist to soften the photoresist thereby shaping the lenses through surface tension and gravity. This reflow technique may also be used shape the profile of the grating elements in the diffractive lens embodiments of FIGS. 10A and 10B. Stepped lens profiles may also be formed for either refractive or diffractive lens elements. Reflow or wet etching may be desirably used on stepped lens to round off step edges to product a smoother lens profile. Gray scale photolithographic masks may also be used to produce substantially curved lens profiles.

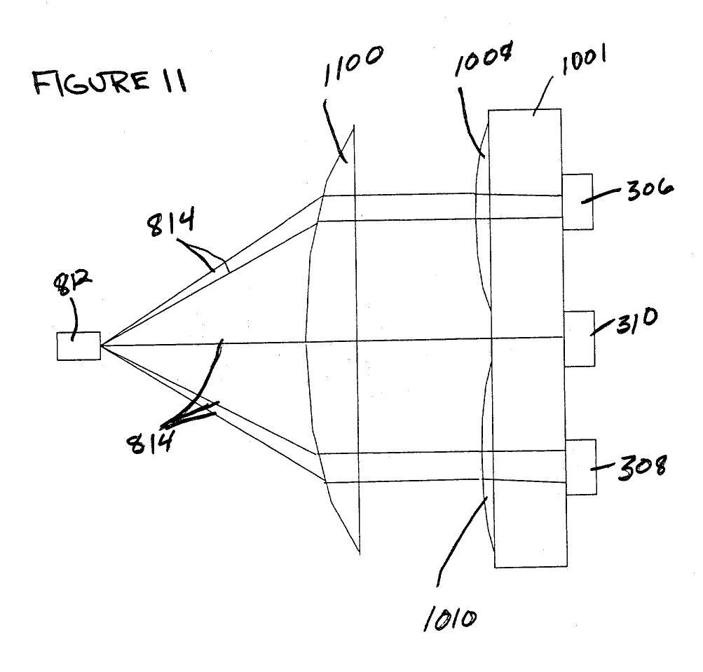

It is noted that with the monolithic lens embodiment of FIG. 10C it may be desirable to use an additional, separate collimating optic element 1100 between the laser and the wavelength locker to pre-collimate the light 814, as shown in FIG. 11. This arrangement, using separate collimating optic element 1100 to pre-collimate the light, may be used with any of the previously described exemplary etalon based wavelength lockers, but may be particularly desirable with the monolithic lens embodiment of FIG. 10A. Etalon 1001 may represent a solid or an air-spaced etalon.

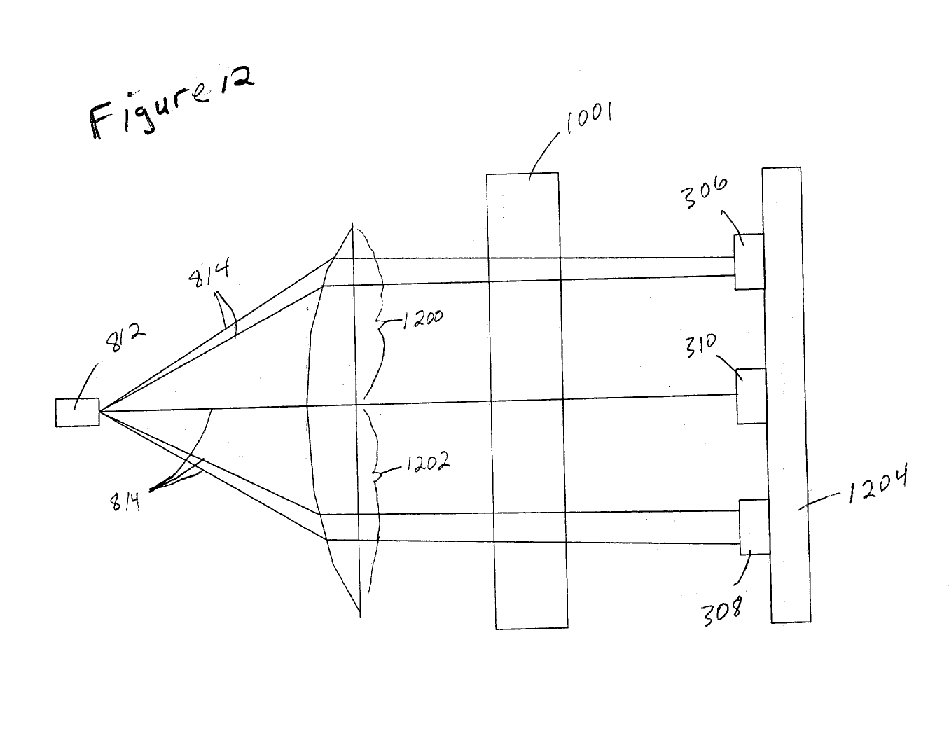

FIG. 12 illustrate another alternative exemplary etalon based wavelength locker in which the separate collimating optic has two collimating portions 1200 and 1202, which have different focal lengths. The two collimating portions may be a refractive optical element, as shown in FIG. 12, or may be a diffractive or hybrid optical element (not shown). FIG. 12 also shows photodetectors 306, 308, and 310 mounted on a separate substrate 1204. It is noted that exemplary embodiment of FIG. 12 may alternatively be formed without separate substrate 1204 and that photodetectors 306, 308, and 310 may be coupled to the back surface of etalon 1001, as described above. It is also contemplated that in the exemplary embodiments described above with regard to FIGS. 3 and 8, it may be desirable for the photodetectors 306, 308, and 310 to be mounted on a separate substrate 1204, as shown in FIG. 12, instead of being mounted on the back surface of the etalon (or formed within second substrate 804 of FIG. 8).

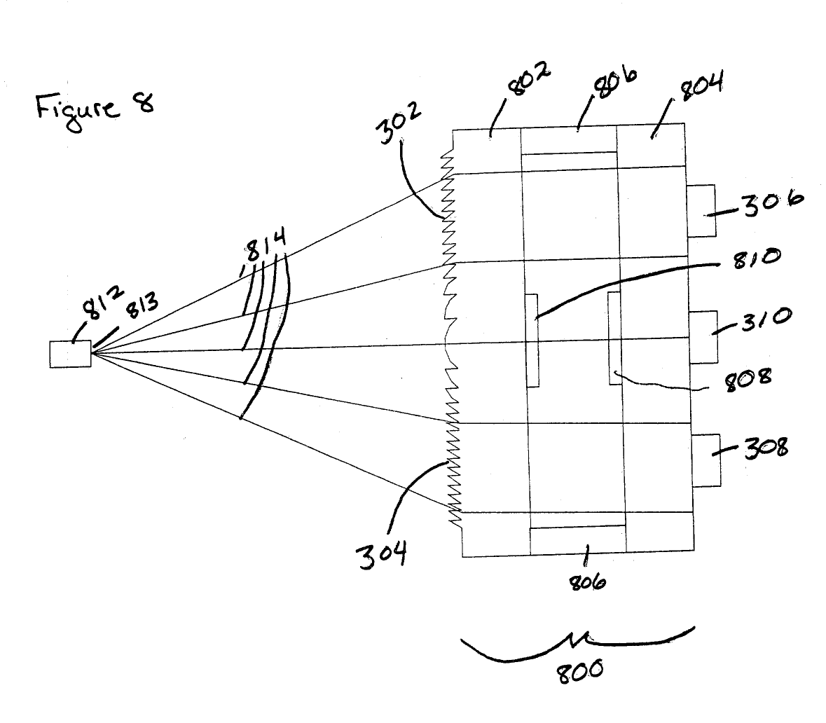

An anti-reflective (AR) dielectric coating may be deposited on a portion of the back surface of the substrate, step 406. The AR coating may be deposited by sputtering, e-beam evaporation, or another standard semiconductor processing technique. By lowering the reflectivity of this portion of the back surface of the substrate below 1-2%, the etalon effect is suppressed in this portion of the substrate and light may pass through without introducing a wavelength dependent term. The AR coating 312 may be desirably located in the center of the back surface of substrate 300, as shown in FIG. 7, which illustrates the exemplary wavelength locker at this step of the manufacture, or may be located in another convenient location on the back surface of the substrate. Alternatively, for substrates coated with a metal or dielectric mirror, it may be possible to suppress the etalon effect in a small portion of the substrate by removing the coating from, or not depositing the coating on, a portion of the back surface, and possibly a corresponding portion of the front surface, of the substrate. This approach may be particularly desirable for low refractive index substrates, i.e. those with indices of refraction less than about 2.

A photodetector 310 may be coupled to the AR coating 312, step 408 (or possibly the portion of the back surface which is not coated for metal and dielectric mirror coated substrates). The photodetector 310 is desirably coupled to the surface with an optical epoxy, or possibly a thermoplastic or photoresist, which is highly transmissive in the wavelength band of interest. Approximate matching of the index of refraction between the AR coating (or substrate), optical epoxy or thermoplastic, and the input window of the photodetector is desirable. The photodetector may be any type of miniature photodetector, such as a photodiode or photoresistor, which is sensitive in the wavelength band of interest. The photodetector may be electrically coupled to the analysis circuitry via flip chip connections or wire bonding.

Alternatively, the photodetector may be soldered to metalized pads (not shown) on the back surface of substrate 300 next to AR coating 312 (or the corresponding portion of bare substrate) to provide both mechanical and electrical coupling. If the wavelength independent intensity of the laser is monitored by a photodetector that is not coupled to the back surface of etalon, then steps 406 and 408 may be skipped. In these exemplary embodiments there may be an empty space between the photodetector and the back surface of the substrate.

Photodetectors are also coupled to the back surface of the substrate in locations corresponding to the collimating lens sections, step 410, one photodetector for each collimating lens section. These photodetectors may be any type of miniature photodetector, such as a photodiode or photoresistor, which is sensitive in the wavelength band of interest. The photodetectors are desirably coupled to the surface with an optical epoxy, or possibly a thermoplastic or photoresist, which is highly transmissive in the wavelength band of interest. Approximate matching of the index of refraction between the optical epoxy, photoresist, or thermoplastic and the input window of the photodetector is desirable. For uncoated substrates and substrates coated with dielectric mirrors, it is desirable for the index of refraction of the optical epoxy or thermoplastic to be low relative to the substrate material, desirably one half or less of the refractive index of the substrate. For substrates coated with dielectric mirrors it may be desirable to select a lens material with a relatively low refractive index to improve performance of the dielectric mirror. The photodetectors may be electrically coupled to the analysis circuitry via flip chip connections or wire bonding.

FIGS. 3A and 3B show an exemplary embodiment with two photodetectors 306 and 308 located approximately equidistant from a vertical center line 314 along a line perpendicular to the center line and corresponding to two collimating lens sections 302 and 302. The center line desirably intersects the optical axis of the incident light. This arrangement may allow approximately the same peak intensity light to be incident on photodetectors 306 and 308.

FIG. 8 illustrates an alternative exemplary embodiment of an etalon based wavelength locker. This exemplary embodiment includes an air-spaced etalon 800, formed with two substrates 802 and 804 separated by spacers 806. In this exemplary embodiment, the surfaces of substrates 802 and 804 facing each other are substantially parallel and the air-space between the substrates serves as the etalon. The air-space may be filled with gases, such as dry air, oxygen, nitrogen, carbon dioxide, or a noble gas, or may be substantially evacuated. Collimating optic sections 302 and 304, which have different focal lengths substantially collimate light rays 814 from laser 812 as they enter air-spaced etalon 800. Photodetector 306 measures the wavelength dependent intensity of light transmitted through collimating optic section 302 and air-spaced etalon 800. Photodetector 308 measures the wavelength dependent intensity of light transmitted through collimating optic section 304 and air-spaced etalon 800. Optional photodetector 310 may be used to monitor the wavelength independent intensity of the laser.

The substrates 802 and 804 may desirably be formed of a dielectric with a low absorptivity in the wavelength band of interest. The air-space facing surfaces of the substrates may be planarized. A dielectric or metal mirror coating layer may be deposited on the surfaces of the substrate facing the airspace. Controlling the reflectivity of the etalon surfaces allows control of the finesse of the etalon. Selection of a relatively low finesse, such as a finesse of approximately 4 or less, may be desirable, as described above with reference to FIGS. 3A and 3B.

If the substrates are formed of a material, such as silicon, fused silica, or germanium, with a high index of refraction, the air-space facing surfaces may have sufficient reflectivity to obtain a desired finesse without a coating layer.

The exemplary embodiment illustrated in FIG. 8 includes AR coating layers 808 and 810 located on central portions of the air-space facing surfaces of substrates 804 and 802, respectively. If the wavelength independent intensity of the laser is not monitored in the wavelength locker, then these AR coating layers may be omitted. These AR coating layers may serve to reduce to etalon effect in this portion of air-space etalon, allowing photodetector 310 to monitor the wavelength independent intensity of laser 812. If the air-space facing surfaces of substrates 802 and 804 are coated with metal or dielectric mirror layer, then the portions of these coatings located where AR coating 808 and 810 are shown in FIG. 8 may desirably be removed. Alternatively, the mirror coating may be not deposited in these areas. It is noted that if the reflectivity of the air-space facing substrate surfaces is low enough, one, or both, of the AR coating layers 808 and 810 may be omitted.

Semiconductor lasers may be temperature controlled over a range of on the order of 100° C., typically between −5° C. and 75° C., and in many applications it is desirable for a wavelength locker to be mounted within the laser package on a substrate which is thermally coupled to the semiconductor laser. Therefore, it may be desirable to reduce any thermal effects on the performance of a wavelength locker. At least two factors may lead to changes, due to temperature, in the transmission versus wavelength characteristics of an etalon. These two factors are the thermally induced changes in the index of refraction of the etalon material and thermal expansion of the etalon material. Both of these effects may alter the optical distance between the reflectors of the etalon.

One possible advantage of an air-space etalon is reduction of thermal effects on the transmission versus wavelength characteristics of the etalon. The index of refraction of air has relatively little thermal dependence. The physical separation of etalon reflectors is determined by the thickness of the spacers 806 used to couple the substrates. Two spacers 806 are shown in FIG. 8 one on the top and one on the bottom of air-spaced etalon 800, but it is contemplated that a larger number of spacers may be used, or that a single spacer may surround the edge of air-spaced etalon 800. These spacers are desirably mechanical elements of the etalon, but not optical elements. Therefore, the spacers may be formed of a material chosen to have a low thermal expansion coefficient, including iron nickel alloys, such as Invar®, glass ceramic composites, such as Zerodur®, borosilicate glass, and titanium silicate glasses, such as ULE®.

The magnitude of the thermal dependence of the index of refraction of air is approximately 0.775×10⁻⁶ per ° C., or about one tenth that of solid etalon materials such as fused silica. Additionally, the thermal dependence of the index of refraction of air is negative in sign. In an air-spaced etalon, though, the actual, “physical length” of the air-space increases with temperature. Increasing the physical length of a light path increases its optical length. Therefore, it may be possible to further lower the thermal dependence of the transmission spectrum of an air-spaced etalon by choosing a spacer material with a thermal expansion coefficient approximately in magnitude to the thermal dependence of the index of refraction of air, such as fused silica (thermal expansion coefficient of approximately 0.52×10⁻⁶ per ° C.). In an exemplary embodiment of an air-spaced etalon in which the thermal expansion of the spacer is used to compensate for a negative thermal change in refractive index of the air-space material, it is preferable for the air-space to contain a gas. Therefore, the air-space should not be evacuated in this exemplary embodiment.

Although FIG. 8 shows collimating optic sections 302 and 304 formed on the front surface of substrate 802, it is contemplated that these collimating optic sections may be a separate element positioned between laser 812 and air-spaced etalon 800 or may include a pre-collimating lens positioned between laser 812 and air-spaced etalon 800 as described above with respect to the exemplary lens embodiments of FIGS. 10A, 10C, and 10D. The collimating optic section 302 and 304 may be fabricated on the front surface of substrate 802 as described above with respect to the exemplary method of FIG. 4. Alternatively, the collimating optic sections 302 and 304 may be etched in the front surface of substrate 802 as a diffractive, refractive or hybrid lens. In this manner, the lens 108 is pre-aligned with the etalon 100 and the alignment sensitivity is reduced, while the space required in the package is minimized. The alignment sensitivity may be reduced because the collimated beam is aligned and fixed to the etalon 100 to prevent relative motion between output beam, wavelength monitoring etalon and the photodetectors 306, 308, and 310. It is also noted that either forming collimating optic sections 302 and 304 on the front surface of substrate 802 or etching collimating optic sections 302 and 304 into the front surface of substrate 802 may desirably reduce any possible etalon effect of substrate 802 due to reflections between the front and back surfaces. This may also reduce the space necessary to accommodate the exemplary air-spaced etalon and lead to a significantly smaller overall package for the integrated optical component in which air-spaced etalon 800 is included.

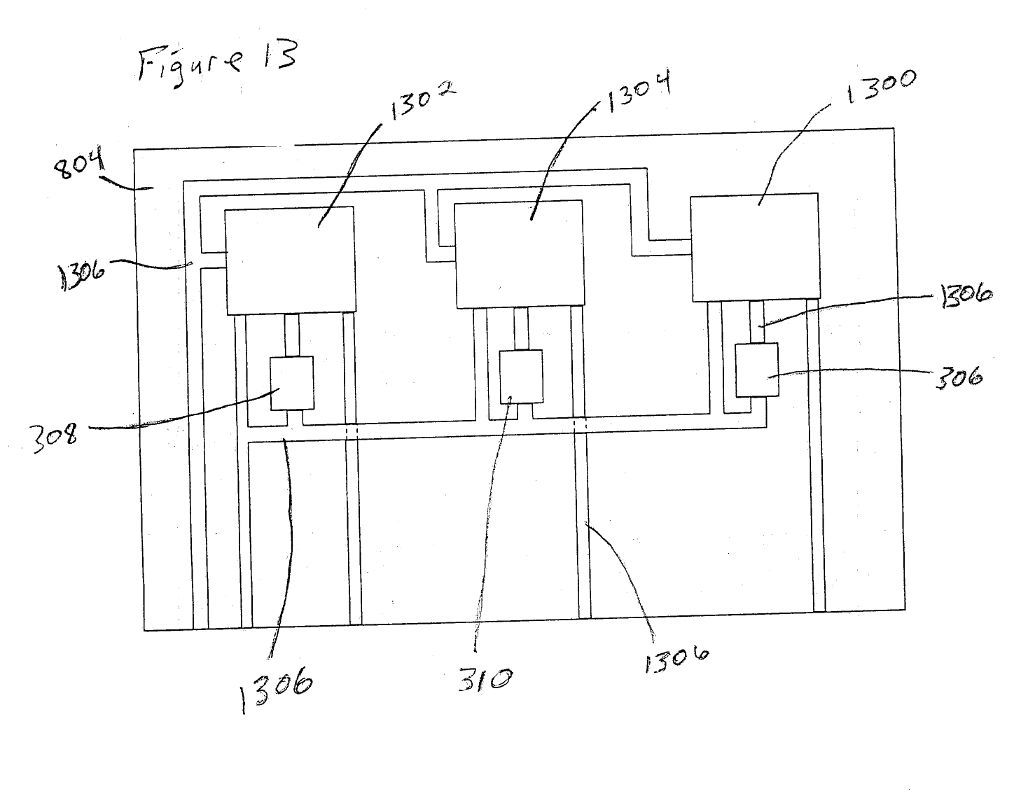

Photodetectors 306, 308, and 310 are desirably coupled to the back surface of substrate 804 and may be electrically attached via flip chip or wire bonding. Electrical traces may be run to the top or bottom of the substrate 804 to allow for wire bonding to connectors in the package wall. FIG. 13 illustrates an exemplary substrate 804 with surface mount operational amplifiers (op-amps) 1300, 1302, and 1304 coupled to the back surface of the substrate, as well as photodetectors 306, 308, and 310. Conductive traces 1306 are formed on the back surface of the substrate 804 to electrically couple the op-amps and photodetectors and op-amps to each other and to allow coupling to additional circuitry located off of the substrate. Alternatively, op-amps 1300 may be coupled to the top edge of the substrate.

In an exemplary embodiment, photodetectors 306, 308, and 310 may be PIN photodiodes and surface mount op-amps 1300, 1302, and 1304 may be configured in a transimpedance amplifier (TIA) configuration. The monitoring PIN photodiodes 306, 308, and 310 are attached to the TIA's 1300, 1302, and 1304, respectively. The PIN photodiodes may produce relatively low level photocurrents (in the microamp to nanoamp range) and may be susceptible to inductively and capacitively coupled noise if their leads are brought out of the optical component package in which the etalon is mounted. The effects of this noise may be reduced by converting the low-level photocurrents into buffered voltages, before transmitting the signal outside of the optical component package. By coupling TIA's 1300, 1302, and 1304 to the back surface (or top edge) of substrate 804, the photocurrents may be converted into buffered voltages in the optical component package without the addition of an amplifier circuit board in the package. Each TIA is electrically coupled to a PIN photodiode by conductive traces 1306 to which it may be flip chip bonded. The PIN photodiodes may also be coupled to conductive traces 1306 using flip chip bonding, or using wirebonding.

Alternatively, substrate 804 may be a semiconductor substrate such as silicon, germanium, or a III/V material such as InP, GaAs, InSb, or AlGaAs. The substrate may also be a multi-layer material such as an InP base with an AlGaAs layer formed on the back surface. Since only the front surface of substrate 804 desirably provides a reflecting surface for air-spaced etalon 800, this semiconductor substrate may be used to fabricate photodetectors 306, 308, and 310 monolithically within substrate 804, before adding any desired coating to the front surface. For example, silicon or InGaAs PIN photodiodes or InGaAs photoresitors may be formed within substrate 804. Such monolithic construction may further increase alignment accuracy and may also reduce the overall size of the exemplary etalon based wavelength locker.

Additionally, it may be desirable to fabricate other amplifier, analysis, and control circuitry directly within substrate 804, providing a buffered voltage signal output for control of laser 812. This may further reduce the size of the complete wavelength locker. The integrated circuitry within substrate 804 may be designed and manufactured utilizing standard semiconductor fabrication techniques.

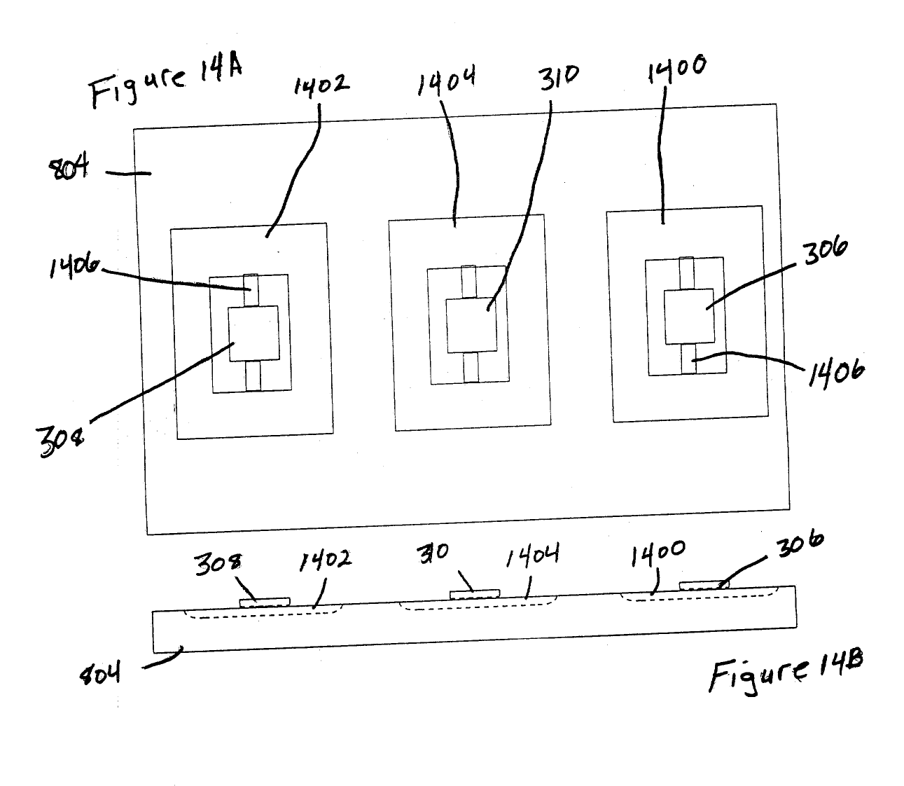

FIGS. 14A and 14B illustrate an exemplary embodiment of substrate 804 that includes integrated circuitry. In this exemplary embodiment, substrate 804 used as a substrate for op-amp integrated circuits 1400, 1402, and 1404. For an air-spaced etalon with silicon substrates, typical silicon IC processes may be used to form op-amp integrated circuits 1400, 1402, and 1404. These integrated circuits may be formed by a standard CMOS amplifier formation technique. Dopants may be diffused into the back surface of the substrate. Exemplary op-amp integrated circuits 1400, 1402, and 1404 formed by diffusion are shown in phantom in FIG. 14B. As shown in FIG. 14A, the portions of the substrate used for the integrated circuitry preferably do not extend beneath the areas of the surface where the photodetectors are coupled. An oxide layer may then be formed and etched to define contact regions. Then a metalization eayer may be formed to connnect the circuitry. Metalized pads 1406 are also formed on the back surface of substrate 804. Photodetectors 306, 308, and 310 are mounted on the back surface of substrate 804 and coupled to op-amp integrated circuits 1400, 1402, and 1404, respectively, via metalized pads 1406.

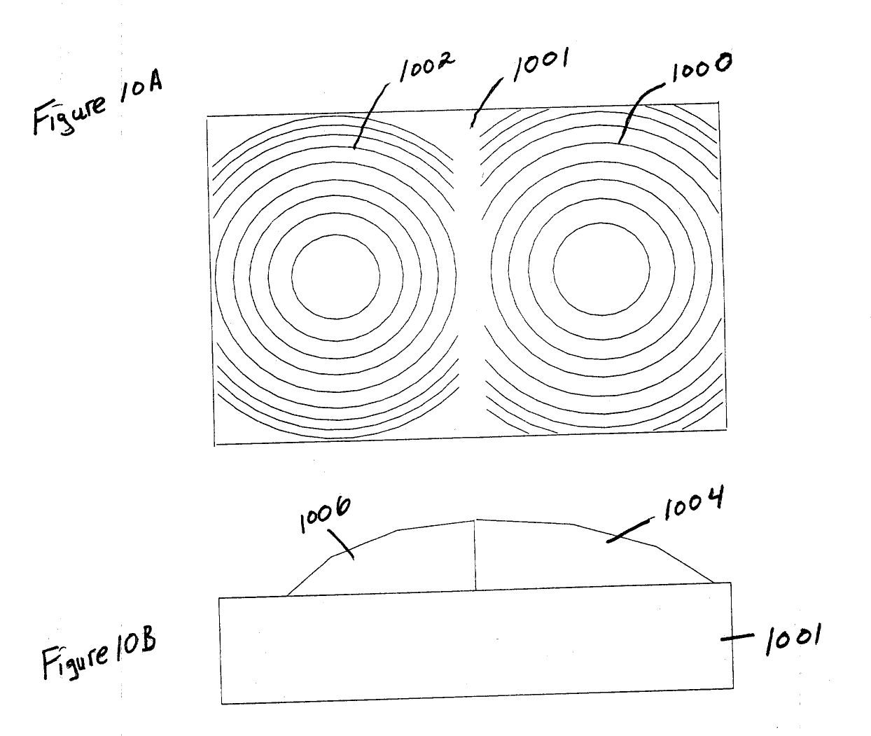

One exemplary method for using an etalon based wavelength locker is illustrated in FIG. 9. A laser 812 is mounted onto mounting substrate 900 using an epoxy or solder layer 902 or other standard means and mounting substrate 900 is coupled to the base 901. Etalon 906 may be coupled to base 901, as shown or may be mounted on mounting substrate 900. As shown in FIG. 9, a portion of the leakage light from the rear facet 813 of laser 812, rays 910, may be desirably coupled into collimating optics 908 and etalon 906. Some of the leakage light from the back facet of laser may reflect off the mounting substrate 900 and undesirably couple into the collimating optics 908 (e.g. rays 912, shown in phantom). This may cause noise and erroneous signals within the etalon based wavelength locker, thereby degrading the wavelength locking performance of the device. In the exemplary embodiment of FIG. 9, this phenomenon may be suppressed by the addition of grating 904 formed on a portion of the top surface of mounting substrate 900. This grating may be formed by standard techniques, such as etching regularly spaced lines in the surface mounting substrate 900 or depositing lines of material on the surface to form a diffraction grating, as shown in FIG. 9. It is noted that grating 904 may extend under part of laser 812 or the entire top surface of mounting substrate 900. Grating 904 is desirably designed such that the portion of the leakage light incident on the grating 904 may be diffracted (e.g. as beams 914) out of the field of view of the collimating optics 908, throughout the anticipated wavelength range of the laser. It is contemplated that, although FIG. 9 illustrates the use of a mounting substrate with a monolithic grating to reduce the coupling unwanted reflections into an etalon based wavelength locker, this embodiment is only exemplary and the use of a mounting substrate with a monolithic grating may be desirable for other optical coupling applications.

While the invention has been described with respect to particular embodiments, those of ordinary skill in the art will appreciate variations in structure and substitutions of materials that are within the scope and spirit of the invention.

What is claimed:

1. A semiconductor laser chip including a semiconductor laser and an optical detector to monitor a detection portion of optical leakage from a rear facet of the semiconductor laser, the semiconductor laser chip comprising:
a mounting substrate including;
a dielectric material with a top surface; and
a diffraction grating portion of the top surface of the mounting substrate having a grating period selected to substantially diffract incident light of a predetermined range of wavelengths in a predetermined range of angles relative to the top surface of the mounting substrate;
the semiconductor laser adapted to produce light in the predetermined range of wavelengths and coupled to the mounting substrate such that a rear facet of the semiconductor laser is adjacent and substantially perpendicular to the diffraction grating portion of the top surface of the mounting substrate; and
an optical detector configured such that a detection portion of optical leakage from the rear facet of the semiconductor laser is incident on the optical detector and the diffracted portion of the optical leakage from the rear facet of the semiconductor laser diffracted by the diffraction grating portion of the mounting substrate is not incident of the optical detector.

2. The semiconductor laser chip of claim 1, further comprising:
an optical element located between the semiconductor laser and the optical detector such that the detection portion of optical leakage from the rear facet of the semiconductor laser is optically coupled to the optical detector through the optical element.

3. The semiconductor laser chip of claim 2, wherein the optical element includes at least one of a diffractive lens element, a refractive lens element, a hybrid lens element, and an etalon.

4. The semiconductor laser chip of claim 1, wherein the diffraction grating portion of the top surface of the mounting substrate includes at least one of:
lines etched in the top surface of the surface of the mounting substrate corresponding to the grating period;
lines formed on the top surface of the surface of the mounting substrate corresponding to the grating period; and
variations in a refractive index of the mounting substrate along the top surface of the surface of the mounting substrate corresponding to the grating period.

5. A wavelength selective detector comprising:
a base having a top surface;
a first substrate substantially transparent to a wavelength of interest;
coupled to the top surface of the base; and
having an optics surface and a first reflecting surface substantially perpendicular to the top surface of the base;
a first collimating optical element formed on a first optics portion of the optics surface of the first dielectric substrate, the first collimating optical element having a first focal length to substantially collimate, within the first substrate, a first portion of light from a predetermined source;
a second collimating optical element formed on a second optics portion of the optics surface of the first dielectric substrate, the second collimating optical element having a second focal length, shorter than the first focal length, to substantially collimate, within the first substrate, a second portion of light from the predetermined source;
a second substrate substantially transparent to the wavelength of interest;
coupled to the top surface of the base; and
having a second reflecting surface and a detector surface substantially perpendicular to the top surface of the base, the second reflecting surface substantially parallel to and facing the first reflecting surface of the first substrate;
a first optical detector configured to receive the first portion of light from the predetermined source after the first portion of light from the predetermined source passes through the second substrate; and
a second optical detector configured to receive the second portion of light from the predetermined source after the second portion of light from the predetermined source passes through the second substrate.

6. The wavelength selective detector of claim 5, wherein:
the first substrate is formed from at least one of InP, GaAs, InSb, AlGaAs, silicon, fused silica, germanium, sapphire, NaCl, glass ceramic composite, borosilicate glass, and titanium silicate glass; and
the second substrate is formed from at least one of InP, GaAs, InSb, AlGaAs, silicon, fused silica, germanium, sapphire, NaCl, glass ceramic composite, borosilicate glass, and titanium silicate glass.

7. The wavelength selective detector of claim 5, further comprising:
a spacer configured to hold the first substrate and the second substrate in a predetermined spatial relationship, the spacer having a coefficient of thermal expansion less than about 1.5×10⁻⁶ per ° C.

8. The wavelength selective detector of claim 7, wherein the spacer is formed from at least one of fused silica, iron nickel alloy, glass ceramic composite, borosilicate glass, and titanium silicate glass.

9. The wavelength selective detector of claim 5, further comprising a third collimating optical element optically coupled to the first collimating optical element and the second collimating optical element to substantially collimate light incident on the first collimating optical element and the second collimating optical element from the predetermined source.

10. The wavelength selective detector of claim 5, wherein:
the first collimating optical element includes at least one of a diffractive lens element, a refractive lens element, and a hybrid lens element; and
the second collimating optical element includes at least one of a diffractive lens element, a refractive lens element, and a hybrid lens element.

11. The wavelength selective detector of claim 5, wherein:
the first collimating optical element is formed from at least one of amorphous SiO₂, SiN, optical epoxy, and photoresist; and
the second collimating optical element is formed from at least one of amorphous SiO₂, SiN, optical epoxy, and photoresist.

12. The wavelength selective detector of claim 5, further comprising:
an antireflection coating formed on a portion of the first reflecting surface of the first substrate; and
a third optical detector configured to receive a third portion of light from the predetermined source that passes through the antireflection coating.

13. The wavelength selective detector of claim 5, further comprising:
an antireflection coating formed on a portion of the second reflecting surface of the second substrate; and
a third optical detector configured to receive a third portion of light from the predetermined source that passes through the antireflection coating.

14. The wavelength selective detector of claim 5, wherein:
the first optical detector is mounted to a first detector portion of the detector surface of the second substrate; and
the second optical detector is mounted to a second detector portion of the detector surface of the second substrate.

15. The wavelength selective detector of claim 14, wherein the first optical detector and the second optical detector are flip chip bonded to the detector surface of the second substrate.

16. The wavelength selective detector of claim 14, further comprising:
a first amplifier circuit coupled to the second substrate and electrically coupled to the first optical detector; and
a second amplifier circuit coupled to the second substrate and electrically coupled to the second optical detector.

17. The wavelength selective detector of claim 14, wherein:
a plurality of conductive traces are formed on the detector surface of the second substrate;
the first optical detector is electrically coupled to at least two of the plurality of conductive traces formed on the detector surface of the second substrate; and
the second optical detector is electrically coupled to at least two of the plurality of conductive traces formed on the detector surface of the second substrate.

18. The wavelength selective detector of claim 5, wherein:
the first optical detector is formed on a first detector portion of the detector surface of the second substrate; and
the second optical detector is formed on a second detector portion of the detector surface of the second substrate.

19. The wavelength selective detector of claim 5, wherein:
the first optical detector is at least one of a photodiode and a photoresistor; and
the second optical detector is at least one of a photodiode and a photoresistor.

20. The wavelength selective detector of claim 5, further comprising:
a first reflective coating on the first reflective surface of the first substrate, and the first reflective coating is at least one of a metallic layer and a dielectric mirror; and
a second reflective coating on the second reflective surface of the second substrate, and the second reflective coating is at least one of a metallic layer and a dielectric mirror.

21. The wavelength selective detector of claim 5, wherein the second substrate is formed of a semiconductor material and further includes amplifier circuitry, the amplifier circuitry electrically coupled to the first optical detector and the second optical detector to provide a first amplified signal proportional to a first intensity of the first portion of light from the predetermined source and a second amplified signal proportional to a second intensity of the second portion of light from the predetermined source.

22. The wavelength selective detector of claim 21, wherein the second substrate further includes:
analysis circuitry electrically coupled to the amplifier circuitry to provide an analysis signal proportional to a wavelength of light from the predetermined source based on the first amplified signal and the second amplified signal; and
control circuitry electrically coupled to the analysis circuitry to provide a control signal to the predetermined source based on the analysis signal and the wavelength of interest.

23. The wavelength selective detector of claim 5, further comprising:
a first reflective coating on a first portion and a second portion of the first reflecting surface of the first substrate; and
a second reflective coating on a first portion and a second portion of the second reflecting surface of the second substrate;
wherein the second reflector coating is configured such that the first portion of light from the predetermined source passes through the first portion of the second reflecting surface of the second substrate and the second portion of light from the predetermined source passes through the second portion of the second reflecting surface of the second substrate.

24. The wavelength selective detector of claim 23, further comprising a third optical detector configured to receive a third portion of light from the predetermined source that passes through a third portion of the second reflecting surface of the second substrate.

25. The wavelength selective detector of claim 24, further comprising an antireflection coating formed on the third portion of the second reflecting surface of the second substrate.

26. The wavelength selective detector of claim 24, further comprising:
an antireflection coating formed on a third portion of the first reflecting surface of the first substrate;
wherein the second reflector coating is configured such that the third portion of light from the predetermined source passes through the third portion of the first surface of the first reflecting surface of the first substrate.

27. A wavelength selective detector comprising:
an etalon having a first surface and a second surface, the first surface being substantially parallel to the second surface;
a first collimating optical element optically coupled to a first optics portion of the first surface of the etalon, the first collimating optical element having a first focal length to substantially collimate, within the etalon, a first portion of light from a predetermined source;
a second collimating optical element optically coupled to a second optics portion of the first surface of the etalon, the second collimating optical element having a second focal length, shorter than the first focal length, to substantially collimate, within the etalon, a second portion of light from the predetermined source;
a first optical detector configured to receive the first portion of light from the predetermined source after the first portion of light from the predetermined source passes through the etalon; and
a second optical detector configured to receive the second portion of light from the predetermined source after the second portion of light from the predetermined source passes through the etalon.

28. The wavelength selective detector of claim 27, wherein the etalon is formed from at least one of InP, GaAs, InSb, AlGaAs, silicon, fused silica, germanium, sapphire, NaCl, glass ceramic composite, borosilicate glass, and titanium silicate glass.

29. The wavelength selective detector of claim 27, wherein:
the first collimating optical element is formed on the first optics portion of the first surface of the etalon; and
the second collimating optical element is formed on the second optics portion of the first surface of the etalon.

30. The wavelength selective detector of claim 29, further comprising a third collimating optical element optically coupled to the first collimating optical element and the second collimating optical element to substantially collimate light incident on the first collimating optical element and the second collimating optical element from the predetermined source.

31. The wavelength selective detector of claim 27, wherein:
the first collimating optical element includes at least one of; a diffractive lens element, a refractive lens element, and a hybrid lens element; and
the second collimating optical element includes at least one of; a diffractive lens element, a refractive lens element, and a hybrid lens element.

32. The wavelength selective detector of claim 27, wherein:
the first collimating optical element is formed from at least one of amorphous SiO₂, SiN, optical epoxy, and photoresist; and
the second collimating optical element is formed from at least one of amorphous SiO₂, SiN, optical epoxy, and photoresist.

33. The wavelength selective detector of claim 27, further comprising:
an antireflection coating formed on a third optics portion of the first surface of the etalon; and
a third optical detector configured to receive a third portion of light from the predetermined source that passes through antireflection coating.

34. The wavelength selective detector of claim 27, further comprising:
an antireflection coating formed on a portion of the second surface of the etalon; and
a third optical detector configured to receive a third portion of light from the predetermined source that passes through antireflection coating.

35. The wavelength selective detector of claim 27, wherein:
the first optical detector is coupled to the first portion of the second surface of the etalon; and
the second optical detector is coupled to the second portion of the second surface of the etalon.

36. The wavelength selective detector of claim 35, wherein the first optical detector and the second optical detector are flip chip bonded to the second surface of the etalon.

37. The wavelength selective detector of claim 35, further comprising:
a plurality of conductive traces is formed on the second surface of the etalon;
the first optical detector is electrically coupled to at least two of the plurality of conductive traces formed on the second surface of the etalon;
a first amplifier circuit coupled to the etalon and electrically coupled to the first optical detector;
the second optical detector is electrically coupled to at least two of the plurality of conductive traces formed on the second surface of the etalon; and
a second amplifier circuit coupled to the etalon and electrically coupled to the second optical detector.

38. The wavelength selective detector of claim 27, wherein:
the first optical detector is at least one of a photodiode and a photoresistor; and
the second optical detector is at least one of a photodiode and a photoresistor.

39. The wavelength selective detector of claim 27, further comprising:
a first reflective coating on the first surface of the etalon, the first reflective coating being at least one of a metallic layer and a dielectric mirror; and
a second reflective coating on the second surface of the etalon, the second reflective coating being at least one of a metallic layer and a dielectric mirror.

40. The wavelength selective detector of claim 27, further comprising:
a first reflective coating on the first optics portion and the second optics portion of the first surface of the etalon; and
a second reflective coating on a first detector portion and a second detector portion of the second surface of the etalon;
wherein the second reflective coating is configured such that the first portion of light from the predetermined source passes through the first detector portion of the second surface of the etalon and the second portion of light from the predetermined source passes through the second detector portion of the second surface of the etalon.

41. The wavelength selective detector of claim 40, further comprising:
a third optical detector configured to receive a third portion of light from the predetermined source that passes through a third detector portion of the second surface of the etalon;
wherein the second reflective coating is configured such that the third portion of light from the predetermined source passes through the third detector portion of the second surface of the etalon.

42. The wavelength selective detector of claim 41, further comprising an antireflection coating formed on the third detector portion of the second surface of the etalon.

43. The wavelength selective detector of claim 41, further comprising:
an antireflection coating formed on a third optics portion of the first surface of the etalon;
wherein;
the third portion of light from the predetermined source passes through the third optics portion of the first surface of the etalon.

44. A method of manufacturing a wavelength selective detector, comprising the steps of:
a) providing a substrate having a first index of refraction, a front surface, and a back surface substantially parallel to the front surface, the front surface having a first portion, a second portion, and a third portion;
b) coupling a first photodetector to a first region of the back surface of the dielectric substrate corresponding to the first portion of the front surface of the substrate;
c) coupling a second photodetector to a second region of the back surface of the substrate corresponding to the second portion of the front surface of the substrate;
d) forming a dielectric lens layer over the front surface of the dielectric substrate, the dielectric lens layer having a second index of refraction less than the first index of refraction; and
e) etching the dielectric lens layer to form:
a first lens section corresponding to the first portion of the front surface of the substrate, the first lens section having a first focal length; and
a second lens section corresponding to the second portion of the front surface of the substrate, the second lens section having a second focal length shorter that the first focal length.

45. The method of claim 44, wherein step (a) includes the step of planarizing the front surface and the back surface of the substrate.

46. The method of claim 44, wherein step (a) includes the step of depositing a reflective coating on at least one of the front surface of the substrate and the back surface of the substrate.

47. The method of claim 46, further comprising the step of:
f) coupling a third photodetector to a third region of the back surface of the substrate corresponding to the third portion of the front surface of the substrate;
wherein step (a) further includes the step of etching the reflective coating to remove the reflective coating from the third region of the back surface of the substrate.

48. The method of claim 44, further comprising the steps of:
f) depositing an antireflection coating on a third region of the back surface of the substrate corresponding to the third portion of the front surface of the substrate; and
g) coupling a third photodetector to the third region of the back surface of the dielectric substrate.

49. The method of claim 44, further comprising the step of:
f) coupling a third photodetector to a third region of the back surface of the dielectric substrate corresponding to the third portion of the front surface of the substrate;
wherein step (a) includes the step of depositing a reflective coating on the front surface and the first region and the second region of the back surface of the dielectric substrate.

50. The method of claim 44, further comprising the steps of:
f) coupling a first amplifier circuit to the dielectric substrate and electrically coupling the first amplifier circuit to the first optical detector; and
g) coupling a second amplifier circuit to the dielectric substrate and electrically coupling the second amplifier circuit to the second optical detector
wherein;
step (a) includes the step of forming a plurality of conductive traces on the back surface of the dielectric substrate;
step (b) includes the step of electrically coupling the first optical detector to at least two of the plurality of conductive traces on the back surface of the dielectric substrate; and
step (c) includes the step of electrically coupling the second optical detector to at least two of the plurality of conductive traces on the back surface of the dielectric substrate.

51. A method of detecting a wavelength of output light of a laser using leakage light from the laser, comprising the steps of:
a) coupling a first portion of the leakage light through a first collimating optic and into an etalon, the first collimating optic having a first focal length;
b) coupling a second portion of the leakage light through a second collimating optic and into the etalon, the second collimating optic having a second focal length which is shorter than the first focal length;
c) attenuating the first portion of the leakage light, in intensity, in the etalon based on the wavelength of the output light of the laser and first predetermined criteria including the first focal length of the first collimating optic;
d) attenuating the second portion of the leakage light, in intensity, in the etalon based on the wavelength of the output light of the laser and second predetermined criteria including the second focal length of the second collimating optic;
e) measuring an intensity of the attenuated first portion of the leakage light;
f) measuring an intensity of the attenuated second portion of the leakage light;
g) determining the wavelength of the output light of the laser by measuring the intensity of the attenuated first portion of the leakage light and the intensity of the attenuated second portion of the leakage light and using the first focal length and the second focal length.

52. The method of claim 51, further comprising the steps of:
j) measuring an intensity of the third portion of the leakage light, the third portion of the leakage light being substantially unattenuated by the etalon.

53. A method of manufacturing a wavelength selective detector, comprising the steps of:
a) providing a substrate having a first index of refraction, a front surface, and a back surface substantially parallel to the front surface, the front surface having a first portion and a second portion;
b) coupling a first photodetector to a first region of the back surface of the substrate corresponding to the first portion of the front surface of the substrate;
c) coupling a second photodetector to a second region of the back surface of the substrate corresponding to the second portion of the front surface of the substrate;
d) forming a first dot of photoresist having a first radius and a second dot of photoresist having a second radius on the front surface of the substrate, the photoresist having a second index of refraction less than the first index of refraction; and
e) heating the first and second dots of photoresist to form;
a first lens corresponding to the first portion of the front surface of the substrate and having a first focal length; and
a second lens corresponding to the second portion of the front surface of the substrate, having a second focal length shorter that the first focal length.

54. An air-spaced etalon comprising:
a first substrate substantially transparent to a wavelength of interest having a first reflecting surface;
a second substrate substantially transparent to the wavelength of interest having a second reflecting surface, the second reflecting surface substantially parallel to and facing the first reflecting surface of the first substrate;
a spacer configured to hold the first substrate and the second substrate in a predetermined spatial relationship, the spacer having a coefficient of thermal expansion in the range of about 0.3×10⁻⁶ per ° C. to about 1.0×10⁻⁶ per ° C.

55. The air-spaced etalon of claim 54, wherein:
the first substrate is formed from at least one of InP, GaAs, InSb, AlGaAs, silicon, fused silica, germanium, sapphire, NaCl, glass ceramic composite, borosilicate glass, and titanium silicate glass; and
the second substrate is formed from at least one of InP, GaAs, InSb, AlGaAs, silicon, fused silica, germanium, sapphire, NaCl, glass ceramic composite, borosilicate glass, and titanium silicate glass.

56. The air-spaced etalon of claim 54, further comprising:
a first reflective coating on the first reflecting surface of the first substrate, the first reflective coating being at least one of a metallic layer and a dielectric mirror; and
a second reflective coating on the second reflecting surface of the second substrate, the second reflective coating being at least one of a metallic layer and a dielectric mirror.

57. The air-spaced etalon of claim 54, wherein a space between the first reflecting surface of the first substrate and the second reflecting surface of the second substrate is filled with a gas selected from the group consisting of dry air, oxygen, nitrogen, carbon dioxide and the noble gasses.
